(19) United States
(12) Patent Application Publication
(10) Pub. No.: US 2023/0212429 A1
(43) Pub. Date: Jul. 6, 2023

(54) SLURRY COMPOSITION FOR METAL FILM FOR CONTACT PROCESS

(71) Applicant: KCTECH CO., LTD., Gyeonggi-do (KR)

(72) Inventors: Jung Yoon KIM, Gyeonggi-do (KR); In Seol HWANG, Gyeonggi-do (KR); Hyun Goo KONG, Gyeonggi-do (KR)

(73) Assignee: KCTECH CO., LTD., Gyeonggi-do (KR)

(21) Appl. No.: 18/088,607

(22) Filed: Dec. 25, 2022

(30) Foreign Application Priority Data
Dec. 31, 2021 (KR) 10-2021-0194166

(51) Int. Cl. C09G 1/02

(52) U.S. Cl. CPC C09G 1/02

(57) ABSTRACT

Provided is a slurry composition for a metal film for a contact process. A polishing slurry composition includes abrasive particles, a compound including one or more functional groups capable of hydrogen bonding, a nonionic polymer including one or more hydrophilic functional groups in a repeating unit structure, and an oxidizer.

### CROSS-REFERENCE TO RELATED APPLICATION

This application claims the benefit of Korean Patent Application No. 10-2021-0194166 filed on Dec. 31, 2021, in the Korean Intellectual Property Office, the entire disclosure of which is incorporated herein by reference for all purposes.

### BACKGROUND

### 1. Field of the Invention

One or more embodiments relate to a polishing slurry composition used for chemical mechanical polishing (CMP) of a metal film for a contact process.

### 2. Description of the Related Art

Recently, there have been required a number of chemical mechanical polishing (CMP) processes for many thin films constituting devices in the field of semiconductor and display industries. A CMP process refers to a process of flatly polishing a surface of a semiconductor wafer using a slurry containing an abrasive and various compounds through a rotation movement while the surface of the semiconductor wafer is in contact with a polishing pad. In general, it is known that a metal polishing process is performed by repeating a process of forming a metal oxide (mOₓ) by an oxidizer and a process of removing the formed metal oxide with abrasive particles. In the metal polishing process, the importance of necessity for reduction of metal dishing, metal erosion, metal loss, and the like is increasing more, and at the same time, the polishing slurry composition needs to maintain a high removal speed, high selectivity for a barrier material, and a low defect.

In the polishing process of a metal layer, which is often used as a wiring of a semiconductor device, an insulating film or a pattern such as a trench may be formed on a lower portion of the metal layer. In this case, in the CMP process, high polishing selectivity is required for the metal layer and the insulating film, and the polishing process occurs continuously. If the selectivity of the slurry is too high, recess may occur on the target layer due to excessive polishing, or the erosion of an insulating layer or a barrier layer by the physical action of abrasive particles may be aggravated. The recess and erosion phenomena described above may act as defects during global planarization of a wafer, and device fault may occur as the defects are accumulated due to stacking.

In a semiconductor device, the metal molybdenum (Mo) is used in an excessive amount at an initial stage, and thus, it is necessary to perform a molybdenum polishing process to achieve surface properties appropriate for the semiconductor manufacture. For the metallic molybdenum surface polishing, a plurality of processes are often required to obtain desired surface roughness and this implies the use of a plurality of machines and/or components and abrasive replacements which may negatively affect processing time for each component. Therefore, it is necessary to develop a polishing slurry composition capable of improving defects such as dishing, erosion, and the like while polishing a metallic molybdenum pattern film.

The above description is information the inventor(s) acquired during the course of conceiving the present disclosure, or already possessed at the time, and was not necessarily publicly known before the present application was filed.

### SUMMARY

In a chemical mechanical polishing (CMP) process of a metal film (e.g., a metal pattern film process or metal electrode process (e.g., a contact process)) during a semiconductor process, a slurry composition having a negative zeta potential, which is a commercially available slurry, has been used. This may contain a slurry of abrasive particles dispersed as negative charges and an anionic polymer additive, and in a case of a slurry additive composition having a negative zeta potential, polishing selectivity to a nitride film is reduced due to a low polishing speed of the abrasive particle slurry on an oxide film, and thus, a level of defects, scratches, etc. may increase or a high dishing level due to over-polishing of an insulating film may occur. Accordingly, the present disclosure provides a polishing slurry composition dispersed as positive charges, and the polishing slurry composition of the disclosure may enable application of abrasive particles having a smaller size to reduce an amount of the abrasive particles, and may implement desired polishing speed and selectivity to prevent defects and scratches. In addition, since the polishing speed is high, polishing selectivity for a polishing target film may be increased.

However, goals to be achieved are not limited to those described above, and other goals not mentioned above are clearly understood by one of ordinary skill in the art from the following description.

According to an aspect, there is provided a polishing slurry composition including abrasive particles, a compound including one or more functional groups capable of hydrogen bonding, a nonionic polymer including one or more hydrophilic functional groups in a repeating unit structure, and an oxidizer.

The compound may include at least one of polyglycerin, polyglycerol polyricinoleate, 1,2,3-propanetriol (a homopolymer, (9Z,12R)-12-hydroxy-9-octadecenoate), a PPG block polymer (an EO/PO copolymer, Ethylan 324), polyacrylic amide, Berol 185, polyacrylic acid, polymaleic acid, polymethacrylic acid, a poly(butadiene-co-maleic acid), a poly(acrylic acid-co-maleic acid), a poly(acrylamide-co-acrylic acid), polycarboxylic acid, poly(acrylic acid-maleic acid), poly(acrylonitrile-butadiene-acrylic acid), poly(acrylonitrile-butadiene-methacrylic acid), poly(acrylic acid-co-maleic acid), poly(methyl methacrylate-co-methacrylic acid), poly(N-isopropylacrylamide-co-methacrylic acid), poly(N-isopropylacrylamide-co-methacrylic acid-co-octadecyl acrylate), poly(tert-butyl acrylate-co-ethyl acrylate-co-methacrylic acid), poly(methyl methacrylate), a methacrylic acid-methylmethacrylate copolymer, poly(methyl vinyl ether-alt-maleic acid), poly(styrene-alt-maleic acid) sodium salt solution, poly(4-styrene sulfonic acid-co-maleic acid) sodium salt, poly(styrene-co-maleic acid) partial isobutyl ester, poly[(isobutylene-alt-maleic acid, ammonium salt)-co-(isobutylene-alt-maleic anhydride)], a poly(methyl vinyl ether-alt-maleic acid monoethyl ester) solution, a polyacrylic acid/sulfonic acid copolymer, a polysulfonic acid/acrylamide copolymer, polyacrylamidemethylpropanesulfonic acid, a polyacrylic acid/styrene copolymer, or a copolymer including at least one repeating unit of polyacrylic acid, polymethacrylic acid, and polymaleic acid and one or more repeating units of polypropylene oxide methacrylic acid, polypropylene oxide acrylic acid, polyethylene oxide methacrylic acid, and polyethylene oxide acrylic acid.

The compound may be in an amount of 0.001 wt % to 5 wt % in the polishing slurry composition.

The nonionic polymer may include at least one of polyethylene glycol, polypropylene glycol, polyvinylpyrrolidone, polyoxyalkylene alkyl ether, polyoxyalkylene alkyl ester, polyoxyethylene methyl ether, polyethylene glycol sulfonic acid, polyvinyl alcohol, polyethylene oxide, polypropylene oxide, polyalkyl oxide, polyoxyethylene oxide, a polyethylene oxide-propylene oxide copolymer, cellulose, methylcellulose, methylhydroxyethylcellulose, methylhydroxypropylcellulose, hydroxyethylcellulose, carboxymethylcellulose, carboxymethylhydroxyethylcellulose, sulfoethylcellulose, or carboxymethylsulfoethylcellulose.

The nonionic polymer may have a molecular weight (weight-average molecular weight) of 800 or more.

The nonionic polymer may be in an amount of 0.0001 wt % to 0.1 wt % in the polishing slurry composition.

The abrasive particles may include a metal oxide, a metal oxide coated with an organic material or an inorganic material, or both the metal oxides, and the metal oxide may include at least one of silica, ceria, zirconia, alumina, titania, barium, germania, mangania, or magnesia.

The abrasive particles may include self-assembly of fine particles, colloidal particles, or both the self-assembly and colloidal particles, and the abrasive particles may include primary particles having a size of 5 nanometers (nm) to 150 nm and secondary particles having a size of 30 nm to 300 nm.

The abrasive particles may be in an amount of 0.1 wt % to 10 wt % in the polishing slurry composition.

The oxidizer may include at least one of hydrogen peroxide, urea hydrogen peroxide, urea, percarbonate, periodic acid, periodate, perchloric acid, perchlorate, perbromic acid, perbromate, perboric acid, perborate, potassium permanganate, sodium perborate, permanganic acid, permanganate, persulfate, bromate, chlorite, chlorate, chromate, dichromate, a chromium compound, iodate, iodic acid, ammonium peroxysulfate, benzoyl peroxide, calcium peroxide, barium peroxide, sodium peroxide, dioxygenyl, ozone, ozonide, nitrate, hypochlorite, hypohalite, chromium trioxide, pyridinium chlorochromate, nitrous oxide, monopersulfate salt, dipersulfate salt, or sodium peroxide.

The oxidizer may be in an amount of 0.0001 wt % to 5 wt % in the polishing slurry composition.

The polishing slurry composition may have pH in a range of 1 to 12.

The polishing slurry composition may further include a pH adjusting agent, a nucleophilic organic material having one or more unshared electron pairs, or both the pH adjusting agent and nucleophilic organic material.

The nucleophilic organic material may include at least one or more of oxalic acid, malic acid, maleic acid, malonic acid, formic acid, lactic acid, acetic acid, picolinic acid, citric acid, succinic acid, tartaric acid, glutaric acid, glutamic acid, glycolic acid, propionic acid, fumaric acid, salicylic acid, pimelinic acid, benzoic acid, butyric acid, aspartic acid, sulfonic acid, or phthalic acid.

The nucleophilic organic material may be in an amount of 0.001 wt % to 5.0 wt % in the polishing slurry composition.

The polishing slurry composition may have a zeta potential of 1 millivolt (mV) to 100 mV.

A polishing target film may be a metal film, an oxide film, or both the metal film and oxide film.

The metal may include at least one of indium (In), tin (Sn), titanium (Ti), vanadium (V), gadolinium (Gd), gallium (Ga), manganese (Mn), iron (Fe), cobalt (Co), copper (Cu), zinc (Zn), zirconium (Zr), hafnium (HO, aluminum (Al), niobium (Nb), nickel (Ni), chromium (Cr), molybdenum (Mo), tantalum (Ta), ruthenium (Ru), or tungsten.

The oxide film may include an oxide including at least one of indium (In), tin (Sn), silicon (Si), titanium (Ti), vanadium (V), gadolinium (Gd), gallium (Ga), manganese (Mn), iron (Fe), cobalt (Co), copper (Cu), zinc (Zn), zirconium (Zr), hafnium (HO, aluminum (Al), niobium (Nb), nickel (Ni), chromium (Cr), molybdenum (Mo), tantalum (Ta), ruthenium (Ru), or tungsten (W).

A polishing speed of the polishing slurry composition for the polishing target film may be 100 Å/min or more.

Polishing selectivity of the polishing target film to a nitride film may be 10 or more.

Selectivity of a polishing speed of the metal film to a static etch rate (SER) of the metal film (the polishing speed of the metal film/the SER of the metal film) may be 5 or more.

Additional aspects of example embodiments will be set forth in part in the description which follows and, in part, will be apparent from the description, or may be learned by practice of the disclosure.

The present disclosure may provide a polishing slurry composition capable of removing a metal film and an oxide film (e.g., Mo/SiOx) in a metal electrode process (e.g., a Mo contact process) in a semiconductor manufacturing process, and implementing planarization by the CMP process by exhibiting polishing stop performance.

The present disclosure may provide a polishing slurry composition capable of preventing dissolution due to chemicals while polishing and effectively removing a metal film, and showing high selectivity of a polishing speed to the SER of the metal film (e.g., the Mo film).

The present disclosure may reduce Δerosion according to pattern density by exhibiting the polishing stop performance when a nitride film is exposed from a pattern wafer.

### DETAILED DESCRIPTION

Hereinafter, the description will be made with reference to embodiments of the disclosure. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In the description of embodiments, detailed description of well-known related structures or functions will be omitted when it is deemed that such description will cause ambiguous interpretation of the present disclosure.

In addition, the terms first, second, A, B, (a), and (b) may be used to describe constituent elements of the embodiments. These terms are used only for the purpose of discriminating one component from another component, and the nature, the sequences, or the orders of the components are not limited by the terms. It should be noted that if it is described in the specification that one component is “connected,” “coupled” or “joined” to another component, the former may be directly “connected,” “coupled,” and “joined” to the latter or “connected”, “coupled”, and “joined” to the latter via another component.

A component having a common function with a component included in one embodiment is described using a like name in another embodiment. Unless otherwise mentioned, the descriptions on the embodiments may be applicable to the following embodiments and thus, duplicated descriptions will be omitted for conciseness.

Hereinafter, embodiments of the present disclosure will be described in detail. When it is determined detailed description related to a related known function or configuration they may make the purpose of the present disclosure unnecessarily ambiguous in describing the present disclosure, the detailed description will be omitted here. In addition, terminologies used herein are defined to appropriately describe the embodiments and thus may be changed depending on a user, the intent of an operator, or a custom of a field to which the present disclosure pertains. Accordingly, the terms must be defined based on the following overall description of this specification.

Throughout the specification, when any component is positioned “on” another component, this not only includes a case that the any component is brought into contact with the other component, but also includes a case that another component exists between two components.

It will be understood throughout the whole specification that, when one part “includes” or “comprises” one component, the part does not exclude other components but may further include the other components.

Hereinafter, a polishing slurry composition according to the present disclosure will be described in detail with reference to embodiments. However, the present disclosure is not limited to such embodiments.

The present disclosure relates to a polishing slurry composition and the polishing slurry composition may include abrasive particles, a compound containing one or more functional groups capable of hydrogen bonding, a nonionic polymer containing one or more hydrophilic functional groups in a repeating unit structure, and an oxidizer.

According to an embodiment of the disclosure, the abrasive particles may include a metal oxide, a metal oxide coated with an organic material or an inorganic material, or both the metal oxides, and the metal oxide may include at least one of silica, ceria, zirconia, alumina, titania, barium, germania, mangania, or magnesia. The abrasive particles may provide high dispersion stability and easily polish a polishing target film, for example, a metal film and/or an oxide film to implement high polishing properties while minimizing defects such as scratches.

For example, the abrasive particles may include self-assembly of fine particles, colloidal particles, or both the self-assembly and colloidal particles, and the self-assembly of the fine particles may be porous.

For example, the abrasive particles may show cationic surface charges by coating, surface substitution, or both thereof with an organic material and/or an inorganic material. For example, colloidal silica abrasive particles may control silica surface charges by substituting the type of a substituent of a silica particle surface, for example, substituting cations such as NH₃⁺ or the like, or controlling density of (or the number of) substituents. For example, cationic surface charges of the colloidal silica abrasive particles may show positive zeta potential of 8 millivolts (mV) or more; 10 mV or more; 15 mV or more; or 40 mV or more with a pH value of 1 to 6 in a liquid carrier.

For example, a method of preparing the abrasive particles is not particularly limited as long as it is a method of preparing a metal oxide particles well known in the technical field of the present disclosure, and hydrothermal synthesis, a sol-gel method, a precipitation method, a co-precipitation method, a filtering method, an aging method, a spray drying method, a thermal evaporation method, or the like may be desirably used. The abrasive particles may include, but are not limited to, abrasive particles prepared by a liquid-phase method. The liquid-phase method may include, for example, a sol-gel method of causing a chemical reaction of abrasive particle precursors in an aqueous solution and growing crystals to obtain fine particles, a co-precipitation method of precipitating abrasive particle ions in an aqueous solution, and hydrothermal synthesis of forming abrasive particles at a high temperature under a high pressure. The abrasive particles prepared by the liquid-phase method may be dispersed so that the surface of the abrasive particles has a positive charge.

For example, the abrasive particles may have at least one or more of spherical, square, needle and plate shapes.

For example, a specific surface area of the abrasive particles may be 31 m²/g or more; 40 m²/g or more; 31 m²/g to 200 m²/g; or 30 m²/g to 150 m²/g. When the specific surface area of the abrasive particles is in the range described above, a high level of polishing speed may be provided by sufficiently securing an area of a contact portion between the abrasive particles and the polishing target film, thereby reducing the occurrence of scratches and dishing on the surface of the polishing target film. The specific surface area may be measured by a Brunauer-Emmett-Teller (BET) method. For example, the specific surface area may be measured by a 6-point BET method according to a nitrogen gas adsorption-flow method using a porosimetry analyzer (Belsorp-II mini by Bell Japan Inc.).

For example, a size of primary particles of the abrasive particles may be 5 nanometers (nm) to 150 nm, and a size of secondary particles thereof may be 30 nm to 300 nm. An average particle size of the abrasive particles may be measured as an average value of particle sizes of a plurality of particles within a field of view which may be measured by a scanning electron microscope analysis, BET analysis, or dynamic light scattering. In the particle size of the primary particles, the particle size of the primary particles should be 150 nm or less to secure particle uniformity, and the polishing rate may be lowered when the particle size of the primary particles is less than 5 nm. When the size of the secondary particles is less than 30 nm, if fine particles are excessively generated due to milling, cleanability may be deteriorated, and an excessive number of defects may occur on surfaces of a substrate, a wafer, and the like used in the polishing process. When the particle size thereof is more than 300 nm, it is difficult to adjust the selectivity due to the excessive polishing, which may cause dishing, erosion, and surface defects. For example, the abrasive particles may include first particles with a size of 10 nm to 50 nm and second particles with a size in the range of greater than 50 nm to 100 nm, and a mixing ratio (mass ratio) of the first particles to the second particles may be 1:0.1 to 10. The size may refer to diameter, length, thickness, etc. depending on the shape of the particles.

For example, the abrasive particles may be mixed particles with a multi-dispersion type of particle size distribution, in addition to a single-size particle. For example, abrasive particles with two different types of average particle sizes may be mixed to have a bimodal particle distribution, or abrasive particles with three different types of average particle sizes may be mixed to have a particle size distribution showing three peaks. Also, abrasive particles with at least four different types of average particle sizes may be mixed to have a multi-dispersion type particle distribution. Relatively large abrasive particles and relatively small abrasive particles may be mixed, to have a better dispersibility, and an effect of reducing scratches on a wafer surface may be expected.

For example, the abrasive particles may be single crystalline particles, but are not limited thereto. When single crystalline abrasive particles are used, a scratch reduction effect may be achieved in comparison to polycrystalline abrasive particles, dishing may be improved, and cleanability after polishing may be enhanced.

For example, the abrasive particles may be in an amount of 0.0001 wt % to 10 wt %; 0.001 wt % to 5 wt %; 0.1 wt % to 5 wt %; or 0.1 wt % to 10 wt % in the slurry composition. When the amount of the abrasive particles is in the range described above, a desired polishing rate may be implemented according to the polishing target film (e.g., the metal film and/or the oxide film) and/or desired selectivity may be implemented by adjusting the polishing rate. When the amount of the abrasive particles is less than 0.5 wt % in the slurry composition, there is a problem regarding a decrease in the polishing speed, and when the amount of the abrasive particles is more than 10 wt %, the number of abrasive particles remaining on a surface of the polishing target film (e.g., the metal film) may increase according to the increase in the amount of the abrasive particles, and secondary defects such as dishing and/or erosion on the pattern due to the over-polishing may occur.

For example, the functional group capable of hydrogen bonding in the compound including one or more functional groups capable of hydrogen bonding may be a silane group, an amine group, an alkoxy group, a carboxy group, a hydroxyl group, and the like.

For example, the compound may include at least one of polyglycerin, polyglycerol polyricinoleate, 1,2,3-propanetriol (a homopolymer, (9Z,12R)-12-hydroxy-9-octadecenoate), a PPG block polymer (an EO/PO copolymer, Ethylan 324), polyacrylic amide, Berol 185, polyacrylic acid, polymaleic acid, polymethacrylic acid, a poly(butadiene-co-maleic acid), a poly(acrylic acid-co-maleic acid), a polyacrylamide-co-acrylic acid, polycarboxylic acid, poly(acrylic acid-maleic acid), poly(acrylonitrile-butadiene-acrylic acid), poly(acrylonitrile-butadiene-methacrylic acid), poly(acrylic acid-co-maleic acid), poly(methyl methacrylate-co-methacrylic acid), poly(N-isopropylacrylamide-co-methacrylic acid), poly(N-isopropylacrylamide-co-methacrylic acid-co-octadecyl acrylate), poly(tert-butyl acrylate-co-ethyl acrylate-co-methacrylic acid), poly(methyl methacrylate), a methacrylic acid-methylmethacrylate copolymer, poly(methyl vinyl ether-alt-maleic acid), poly(styrene-alt-maleic acid) sodium salt solution, poly(4-styrene sulfonic acid-co-maleic acid) sodium salt, poly(styrene-co-maleic acid) partial isobutyl ester, poly[(isobutylene-alt-maleic acid, ammonium salt)-co-(isobutylene-alt-maleic anhydride)], a poly(methyl vinyl ether-alt-maleic acid monoethyl ester) solution, a polyacrylic acid/sulfonic acid copolymer, a polysulfonic acid/acrylamide copolymer, polyacrylamidemethylpropanesulfonic acid, a polyacrylic acid/styrene copolymer, or a copolymer including at least one repeating unit of polyacrylic acid, polymethacrylic acid, and polymaleic acid and one or more repeating units of polypropylene oxide methacrylic acid, polypropylene oxide acrylic acid, polyethylene oxide methacrylic acid, and polyethylene oxide acrylic acid.

For example, the compound may be in an amount of 0.001 wt % to 5 wt %; 0.001 wt % to 2 wt %; or 0.01 wt % to 1 wt % in the polishing slurry composition. When the amount of the compound is in the range described above, a high polishing rate for the polishing target film may be implemented, a polishing stop function may be performed when a polishing stop film (e.g., the nitride film) is exposed, and the pattern dishing, erosion, and loss of the polishing stop film due to over-polishing (e.g., the insulating film) may be reduced.

For example, the hydrophilic group in the nonionic polymer may include at least one of a hydroxy group (—OH), a carboxyl group (—COOH), an ether group, an ester group, an amino group (—NH₂), a ketone group (—CO—), an aldehyde group (—CHO), a sulfonic acid group (—SO₃H), a nitrate group (—NO3), a nitrile group (—CN), a phosphoric acid group, an acetic acid group, or an alkoxy group (—OR, where R is C₁ to C₂₀ aliphatic organic group).

For example, the nonionic polymer may include at least one of polyethylene glycol, polypropylene glycol, polyvinylpyrrolidone, polyoxyalkylene alkyl ether, polyoxyalkylene alkyl ester, polyoxyethylene methyl ether, polyethylene glycol sulfonic acid, polyvinyl alcohol, polyethylene oxide, polypropylene oxide, polyalkyl oxide, polyoxyethylene oxide, a polyethylene oxide-propylene oxide copolymer, cellulose, methylcellulose, methylhydroxyethylcellulose, methylhydroxypropylcellulose, hydroxyethylcellulose, carboxymethylcellulose, carboxymethylhydroxyethylcellulose, sulfoethylcellulose, or carboxymethylsulfoethylcellulose. The number of carbon atoms of each of the alkylene and alkyl may be selected from 1 to 30; 1 to 20; 1 to 10; and 1 to 5.

For example, a molecular weight (weight-average molecular weight) of the nonionic polymer may be 800 or more; 1,000 or more; 1,500 or more; and 3,000 to 800,000. When the molecular weight of the nonionic polymer is not in the range described above, the stability of the slurry composition may be deteriorated due to a deterioration in the dispersibility of the slurry composition, and an etch rate may not be easily controlled or the occurrence of defects such as erosion or dishing may increase on the surface of the polishing target film (e.g., the metal film and/or the oxide film) after the polishing process.

For example, the nonionic polymer may be in an amount of 0.0001 wt % to 5 wt %; 0.001 wt % to 2 wt %; 0.001 wt % to 1 wt %; or 0.001 wt % to 0.1 wt % in the polishing slurry composition. When the amount of the nonionic polymer is in the range described above, the high polishing rate for the polishing target film may be implemented to increase in-plane uniformity, and an appropriate level of selectivity of the polishing target film may be achieved. In addition, the polishing stop function may be provided when the polishing stop film (e.g., the nitride film) may be exposed, and the pattern dishing, erosion, and loss of the polishing stop film due to the over-polishing may be reduced.

According to an embodiment, the oxidizer may provide an appropriate polishing speed by causing oxidation of the polishing target film, and the oxidizer may be in an amount of 0.0001 wt % to 5 wt %; 0.001 wt % to 1 wt %; and 0.01 wt % to 0.1 wt % in the polishing slurry composition. When the amount of the oxidizer is in the range described above, an appropriate polishing speed for the polishing target film may be provided, and surface hardening, erosion occurrence, and corrosion of the polishing target film caused by an increase in the oxidizer amount may be prevented.

For example, the oxidizer may include at least one of hydrogen peroxide, urea hydrogen peroxide, urea, percarbonate, periodic acid, periodate, perchloric acid, perchlorate, perbromic acid, perbromate, perboric acid, perborate, potassium permanganate, sodium perborate, permanganic acid, permanganate, persulfate, bromate, chlorite, chlorate, chromate, dichromate, a chromium compound, iodate, iodic acid, ammonium peroxysulfate, benzoyl peroxide, calcium peroxide, barium peroxide, sodium peroxide, dioxygenyl, ozone, ozonide, nitrate, hypochlorite, hypohalite, chromium trioxide, pyridinium chlorochromate, nitrous oxide, sulfate, potassium persulfate (e.g., K₂S₂O₈), monopersulfate (e.g., KHSO₅) salt, dipersulfate (e.g., KHSO₄ and K₂SO₄) salt, urea peroxide, or sodium peroxide.

According to an embodiment, the polishing slurry composition may further include at least one or more of a pH adjusting agent and a nucleophilic organic material having one or more unshared electron pairs.

According to an embodiment, the pH adjusting agent may be provided to prevent the corrosion of the polishing target film or the corrosion of a polishing device and achieve a pH range appropriate for the polishing performance, and may include an acidic substance or a basic substance, the acidic substance may include at least one or more of nitric acid, hydrochloric acid, phosphoric acid, sulfuric acid, hydrofluoric acid, bromic acid, iodic acid, maleic acid, acetic acid, citric acid, adipic acid, lactic acid, phthalic acid, or salts thereof, and the basic substance may include at least one or more of ammonium methyl propanol (AMP), tetra methyl ammonium hydroxide (TMAH), ammonium hydroxide, potassium hydroxide, sodium hydroxide, magnesium hydroxide, rubidium hydroxide, cesium hydroxide, sodium bicarbonate, sodium carbonate, imidazole, and salts thereof.

According to an embodiment, the nucleophilic organic material having one or more unshared electron pairs may include at least one or more of oxalic acid, malic acid, maleic acid, malonic acid, formic acid, lactic acid, acetic acid, picolinic acid, citric acid, succinic acid, tartaric acid, glutaric acid, glutamic acid, glycolic acid, propionic acid, fumaric acid, salicylic acid, pimelinic acid, benzoic acid, butyric acid, aspartic acid, sulfonic acid, or phthalic acid, and may be in an amount of 0.001 wt % to 5.0 wt %; 0.001 wt % to 1 wt %; or 0.01 wt % to 0.5 wt % in the polishing slurry composition.

The pH value of the polishing slurry composition is desirably adjusted to obtain dispersion stability and proper polishing speed depending on abrasive particles, and the polishing slurry composition may have an acidic pH value range of 1 to 12, desirably 1 to 6; or 2 to 4. Forming an acidic region may be advantageous to the effect of controlling the etch rate and reducing the occurrence of surface defects (e.g., dishing and erosion).

According to an embodiment, the polishing slurry composition may have a zeta potential of 1 mV to 100 mV, desirably, a positive zeta potential of 10 mV to 70 mV. When an absolute value of the zeta potential is great, the particles have strong forces pushing each other and do not cohere well. Thus, the polishing slurry composition may exhibit a high zeta potential absolute value even in an acidic region, and thus implement a high dispersion stability and an excellent polishing performance.

According to an embodiment, the polishing slurry composition may be applied to a polishing process of a semiconductor device and a display device.

According to an embodiment, a polishing speed of the polishing slurry composition for the polishing target film in the polishing (e.g., chemical mechanical polishing (CMP)) process may be 10 Å/min or more; 100 Å/min or more; 200 Å/min or more; 300 Å/min or more; and desirably 200 Å/min to 4,000 Å/min.

According to an embodiment, the polishing slurry composition may be applied to the polishing of a substrate including a metal film, an oxide film, or a film including both the metal film and oxide film. For example, the substrate may be a wafer or a pattern wafer including the metal film, the oxide film, or both the metal film and oxide film.

According to an embodiment, the polishing slurry composition may be applied to the polishing of a semiconductor wafer including a metal bulk film, and may be applied to the polishing of, for example, a metal bulk layer and a barrier metal layer formed on a semiconductor wafer. For example, the semiconductor wafer may be a semiconductor pattern wafer in which an insulating layer is formed on a substrate, a pattern layer including a barrier metal layer is formed on the insulating layer, and a metal bulk layer is formed on the pattern layer.

For example, the insulating layer may be a silicon or a silicon oxide film, and the barrier metal layer may include, for example, metal, a metal alloy, and an intermetallic compound and may include at least one of, for example, indium (In), tin (Sn), silicon (Si), titanium (Ti), vanadium (V), gadolinium (Gd), manganese (Mn), iron (Fe), cobalt (Co), copper (Cu), zinc (Zn), zirconium (Zr), hafnium (Hf), aluminum (Al), niobium (Nb), nickel (Ni), chromium (Cr), molybdenum (Mo), tantalum (Ta), ruthenium (Ru), tungsten (W), neodymium (Nd), rubidium (Rb), gold (Au), platinum (Pt), gallium (Ga), bismuth (Bi), silver (Ag), or palladium (pd).

For example, the pattern layer may be used for a metal wiring, contact plug, a via contact, a trench, and the like.

For example, the metal bulk layer (or the metal layer) may include at least one of indium (In), tin (Sn), silicon (Si), titanium (Ti), vanadium (V), gadolinium (Gd), manganese (Mn), iron (Fe), cobalt (Co), copper (Cu), zinc (Zn), zirconium (Zr), hafnium (Hf), aluminum (Al), niobium (Nb), nickel (Ni), chromium (Cr), molybdenum (Mo), tantalum (Ta), ruthenium (Ru), tungsten (W), neodymium (Nd), rubidium (Rb), gold (Au), or platinum (Pt).

According to an embodiment, the polishing slurry composition may be used in the CMP process of the metal film for the contact process.

According to an embodiment, the polishing slurry composition may be applied to the polishing of a semiconductor wafer including the oxide film and the oxide film may be a silicon oxide film.

According to an embodiment, in the polishing (e.g., the CMP) process using the polishing slurry composition, the polishing selectivity of the polishing target film to the nitride film (polishing target film/nitride film) may be 10 or more; 20 or more; 25 or more; 30 or more; 100 or more; or 20:1 to 100:1. This may provide an automatic polishing stop function for the nitride film. For example, the polishing selectivity of the oxide film (e.g., the insulating film) to the silicon nitride film (oxide/silicon nitride film) may be 10 or more; 20 or more; 25 or more; 30 or more; 100 or more; or 20:1 to 100:1. That is, the function of preventing the dishing and erosion may be provided by preventing the over-polishing on the polishing stop film (e.g., the insulating film).

According to an embodiment, in the polishing (e.g., the CMP) process using the polishing slurry composition, selectivity of the polishing rate of the polishing target film (e.g., the metal film) to a static etch rate (SER, unit: A/min) of the polishing target film (polishing rate/SER) may be 5 or more; 10 or more; 20 or more; 30 or more; or 5:1 to 50:1.

That is, the polishing is stopped when the nitride film is exposed from the pattern wafer such that Δerosion according to pattern density may be 200 Å or less. For example, selectivity of a polishing rate of a metal film (e.g., the Mo film) to an SER of a metal film (e.g., the Mo film) may be 5 or more; 10 or more; 20 or more; 30 or more; or 5:1 to 50:1.

Hereinafter, the present disclosure will be described in detail based on examples and comparative examples.

However, the following examples are only for illustrating the present disclosure, and the present disclosure is not limited to the following examples.

### Examples and Comparative Examples

Polishing slurry compositions of examples were prepared by selecting the nonionic polymer, the compound including one or more functional groups capable of hydrogen bonding, and the nucleophilic organic material according to the components and amounts shown in Table 1, and a polishing slurry composition of a comparative example was prepared according to Table 1.

Table 2 shows the zeta potential and pH values of the polishing slurry compositions prepared in the examples and the comparative example.

TABLE 1

| | Abrasive particles | | | Oxidizer | | Com2 | | Com3 | | Com4 | |
|---|---|---|---|---|---|---|---|---|---|---|---|
| | | Amount | Size | | Amount | | Amount | | Amount | | Amount |
| — | Type | (wt %) | (nm) | Type | (wt %) | Type | (wt %) | Type | (wt %) | Type | (wt %) |
| Example 1 | Colloidal | 0.9 | 15 | H202 | 0.05 | PA | 0.2 | — | — | PN-C | 0.5 |
| | silica | | | | | | | | | | |
| Example 2 | Colloidal | 0.60 | 17 | H202 | 0.05 | PA | 0.2 | C | 0.2 | PN-C | 0.5 |
| | silica | | | | | | | | | | |
| Example 3 | Colloidal | 0.90 | 17 | H202 | 0.05 | PA | 0.2 | C | 0.2 | PN-C | 0.5 |
| | silica | | | | | | | | | | |
| Example 4 | Colloidal | 0.90 | 15 | H202 | 0.05 | PA | 0.2 | — | — | PN-C | 0.5 |
| | silica | | | | | | | | | | |
| Example 5 | Colloidal | 0.90 | 15 | H202 | 0.05 | PA | 0.2 | — | — | PN-C | 0.5 |
| | silica | | | | | | | | | | |
| Example 6 | Colloidal | 0.90 | 15 | H202 | 0.05 | PA | 0.2 | — | — | PN-C | 0.5 |
| | silica | | | | | | | | | | |
| Example 7 | Colloidal | 0.90 | 36 | H202 | 0.05 | PA | 0.2 | — | — | ETHYLAN | 0.02 |
| | silica | | | | | | | | | 324 | |
| Example 8 | Colloidal | 0.90 | 25 | H202 | 0.05 | PA | 0.2 | — | — | BEROL | 0.02 |
| | silica | | | | | | | | | 185 | |
| Example 9 | Colloidal | 0.90 | 20 | H202 | 0.05 | PA | 0.2 | C | 0.2 | PN-C | 0.5 |
| | silica | | | | | | | | | | |
| Example | Colloidal | 0.90 | 16 | H202 | 0.05 | PA | 0.2 | C | 0.2 | PN-C | 0.5 |
| 10 | silica | | | | | | | | | | |
| Example | Colloidal | 0.5 | 42 | H202 | 0.05 | PA | 0.2 | C | 0.1 | PN-A2 | 0.01 |
| 11 | silica^{b} | | | | | | | | | | |
| Example | Colloidal | 0.5 | 37 | H202 | 0.05 | AA | 0.2 | C | 0.1 | PN-A2 | 0.002 |
| 12 | silica^{b} | | | | | | | | | | |
| Example | Colloidal | 0.5 | 40 | H202 | 0.05 | PA | 0.15 | C | 0.1 | PN-A2 | 0.002 |
| 13 | silica^{b} | | | | | | | | | | |
| Comparative | Colloidal | 0.90 | 30 | H202 | 0.05 | PA | 0.2 | Amino | 0.5 | — | 0.002 |
| Example 1 | silica | | | | | | | acid | | | |

In Table 1, colloidal silica refers to BS-1LC and colloidal silica^{b} refers to PL-1-C.
PN-C refers to polyglycerin and PA refers to picolinic acid.

Measurement of Polishing Performance of Polishing Slurry Compositions

In order to evaluate the polishing properties, the polishing performance for a wafer (PE TEOS 20K (Å)) and a pattern wafer (STI SiN Pattern Wafer 2000K (Å), Trench Depth 2K (Å)) was evaluated in the CMP process by using the polishing slurry compositions of the examples and the comparative example. The results are shown in Tables 3 and 4.

[Polishing Conditions]

1. 300 mm CMP equipment—KCTECH's SP-03

2. Platen speed: 68 rpm

3. Spindle speed: 62 rpm

4. Wafer pressure: 1 psi

5. Slurry flow rate: 200 ml/min

6. Pad: IC1000 pad

TABLE 2

| | Physical properties | |
|---|---|---|
| | Zeta | pH |
| Example 1 | 17 | 4.1 |
| Example 2 | 19 | 4.0 |
| Example 3 | 16 | 4.1 |
| Example 4 | 14 | 4.1 |
| Example 5 | 14 | 4.1 |
| Example 6 | 14 | 4.1 |
| Example 7 | 27 | 4.1 |
| Example 8 | 24 | 4.1 |
| Example 9 | 17 | 4.2 |
| Example 10 | 19 | 4.1 |
| Example 11 | 22 | 3.8 |
| Example 12 | 25 | 4.0 |
| Example 13 | 20 | 4.1 |
| Comparative Example 1 | −30 | 4.1 |

TABLE 3

| | Polishing rate | | | SER |
|---|---|---|---|---|
| | (Å/min) | | | (Å/min) |
| | oxide | SiN | Mo | Mo |
| Example 1 | 260 | 8 | 49 | 23 |
| Example 2 | 226 | 5 | 49 | 13 |
| Example 3 | 283 | 7 | 51 | 16 |
| Example 4 | 216 | 8 | 66 | 21 |
| Example 5 | 253 | 6 | 93 | 18 |
| Example 6 | 202 | 7 | 120 | 15 |
| Example 7 | 219 | 6 | 93 | 15 |
| Example 8 | 242 | 7 | 120 | 19 |
| Example 9 | 204 | 4 | 79 | 17 |
| Example 10 | 197 | 1 | 58 | 13 |
| Example 11 | 236 | 5 | 67 | 11 |
| Example 12 | 239 | 3 | 79 | 17 |
| Example 13 | 276 | 4 | 162 | 18 |
| Comparative Example 1 | 57 | 6 | 97 | 41 |

TABLE 4

| | KCT PATTERN @PD 30% | | |
|---|---|---|---|
| | Polishing rate | | |
| | (Å/min) | | |
| | ΔSiN | R-oxide | F-oxide |
| Example 1 | 12 | 91 | 968 |
| Example 2 | 6 | 114 | 1112 |
| Example 3 | 8 | 97 | 982 |
| Example 4 | 17 | 72 | 792 |
| Example 5 | 19 | 55 | 890 |
| Example 6 | 14 | 113 | 852 |
| Example 7 | 19 | 55 | 890 |
| Example 8 | 14 | 113 | 852 |
| Example 9 | 25 | 20 | 803 |
| Example 10 | 38 | 20 | 657 |
| Example 11 | 9 | 90 | 1177 |
| Example 12 | 15 | 70 | 1129 |
| Example 13 | 9 | 100 | 1171 |
| Comparative Example 1 | 67 | 54 | 642 |

Referring to Tables 2 to 4, the polishing slurry composition according to the present disclosure may have excellent polishing performance for the metal film and the oxide film (the insulating film), and may reduce the pattern dishing and loss of the nitride film and reduce Δerosion occurrence by implementing the polishing stop function of the nitride film after the metal film (Mo) and the oxide film polishing. In addition, the function of preventing the dishing and erosion may be provided by preventing the over-polishing on the oxide film (the insulating film) after the exposure of the nitride film, and the in-plane uniformity may be increased after the polishing, since a removal speed of the oxide film (the insulating film) is 200 Å/min or more. Furthermore, when the nitride film is exposed from the pattern wafer, the polishing may be stopped such that Δerosion according to the pattern density may be 200 Å or less.

The present disclosure may provide the polishing slurry composition in which the slurry having a positive zeta potential includes the compound including one or more functional groups capable of hydrogen bonding, and the nonionic polymer, and may provide the polishing slurry composition in which the selectivity of the polishing target film (the oxide film):nitride film (SiN) is 20:1 or more and the selectivity of the polishing rate of the polishing target film (the metal film (e.g., the Mo film)) to the SER of the polishing target film (e.g., the Mo film) is 5:1 or more.

Although the above-mentioned examples have been described by limited examples, those skilled in the art may apply various modifications and alterations from the above-mentioned description. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A polishing slurry composition comprising:
abrasive particles;
a compound comprising one or more functional groups capable of hydrogen bonding;
a nonionic polymer comprising one or more hydrophilic functional groups in a repeating unit structure; and
an oxidizer.

2. The polishing slurry composition of claim 1, wherein the compound comprises:
at least one selected from the group consisting of polyglycerin, polyglycerol polyricinoleate, 1,2,3-propanetriol (a homopolymer (9Z,12R)-12-hydroxy-9-octadecenoate), a PPG block polymer (an EO/PO copolymer, Ethylan 324), polyacrylic amide, Berol 185, polyacrylic acid, polymaleic acid, polymethacrylic acid, a poly(butadiene-co-maleic acid), a poly(acrylic acid-co-maleic acid), a poly(acrylamide-co-acrylic acid), polycarboxylic acid, poly(acrylic acid-maleic acid), poly(acrylonitrile-butadiene-acrylic acid), poly(acrylonitrile-butadiene-methacrylic acid), poly(acrylic acid-co-maleic acid), poly(methyl methacrylate-co-methacrylic acid), poly(N-isopropylacrylamide-co-methacrylic acid), poly(N-isopropylacrylamide-co-methacrylic acid-co-octadecyl acrylate), poly(tert-butyl acrylate-co-ethyl acrylate-co-methacrylic acid), poly(methyl methacrylate), a methacrylic acid-methylmethacrylate copolymer, poly(methyl vinyl ether-alt-maleic acid), poly(styrene-alt-maleic acid) sodium salt solution, poly(4-styrene sulfonic acid-co-maleic acid) sodium salt, poly(styrene-co-maleic acid) partial isobutyl ester, poly[(isobutylene-alt-maleic acid, ammonium salt)-co-(isobutylene-alt-maleic anhydride)], a poly(methyl vinyl ether-alt-maleic acid monoethyl ester) solution, a polyacrylic acid/sulfonic acid copolymer, a polysulfonic acid/acrylamide copolymer, polyacrylamidemethylpropanesulfonic acid, a polyacrylic acid/styrene copolymer, and a copolymer including at least one repeating unit of polyacrylic acid, polymethacrylic acid, and polymaleic acid and one or more repeating units selected from the group consisting of polypropylene oxide methacrylic acid, polypropylene oxide acrylic acid, polyethylene oxide methacrylic acid, and polyethylene oxide acrylic acid.

3. The polishing slurry composition of claim 1, wherein the compound is in an amount of 0.001 wt % to 5 wt % in the polishing slurry composition.

4. The polishing slurry composition of claim 1, wherein the nonionic polymer comprises:
at least one selected from the group consisting of polyethylene glycol, polypropylene glycol, polyvinylpyrrolidone, polyoxyalkylene alkyl ether, polyoxyalkylene alkyl ester, polyoxyethylene methyl ether, polyethylene glycol sulfonic acid, polyvinyl alcohol, polyethylene oxide, polypropylene oxide, polyalkyl oxide, polyoxyethylene oxide, a polyethylene oxide-propylene oxide copolymer, cellulose, methylcellulose, methylhydroxyethylcellulose, methylhydroxypropylcellulose, hydroxyethylcellulose, carboxymethylcellulose, carboxymethylhydroxyethylcellulose, sulfoethylcellulose, and carboxymethylsulfoethylcellulose.

5. The polishing slurry composition of claim 1, wherein the nonionic polymer has a molecular weight (weight-average molecular weight) of 800 or more.

6. The polishing slurry composition of claim 1, wherein the nonionic polymer is in an amount of 0.0001 wt % to 0.1 wt % in the polishing slurry composition.

7. The polishing slurry composition of claim 1, wherein
the abrasive particles comprises:
a metal oxide;
a metal oxide coated with an organic material or an inorganic material; or
both the metal oxides, and
the metal oxide comprises at least one selected from the group consisting of silica, ceria, zirconia, alumina, titania, barium, germania, mangania, and magnesia.

8. The polishing slurry composition of claim 1, wherein
the abrasive particles comprise self-assembly of fine particles, colloidal particles, or both the self-assembly and colloidal particles, and
the abrasive particles comprise primary particles having a size of 5 nanometers (nm) to 150 nm and secondary particles having a size of 30 nm to 300 nm.

9. The polishing slurry composition of claim 1, wherein the abrasive particles is in an amount of 0.1 wt % to 10 wt % in the polishing slurry composition.

10. The polishing slurry composition of claim 1, wherein the oxidizer comprises:
at least one selected from the group consisting of hydrogen peroxide, urea hydrogen peroxide, urea, percarbonate, periodic acid, periodate, perchloric acid, perchlorate, perbromic acid, perbromate, perboric acid, perborate, potassium permanganate, sodium perborate, permanganic acid, permanganate, persulfate, bromate, chlorite, chlorate, chromate, dichromate, a chromium compound, iodate, iodic acid, ammonium peroxysulfate, benzoyl peroxide, calcium peroxide, barium peroxide, sodium peroxide, dioxygenyl, ozone, ozonide, nitrate, hypochlorite, hypohalite, chromium trioxide, pyridinium chlorochromate, nitrous oxide, monopersulfate salt, dipersulfate salt, and sodium peroxide.

11. The polishing slurry composition of claim 1, wherein the oxidizer is in an amount of 0.0001 wt % to 5 wt % in the polishing slurry composition.

12. The polishing slurry composition of claim 1, wherein the polishing slurry composition has pH in a range of 1 to 12.

13. The polishing slurry composition of claim 1, further comprising:
a pH adjusting agent;
a nucleophilic organic material having one or more unshared electron pairs; or
both the pH adjusting agent and nucleophilic organic material.

14. The polishing slurry composition of claim 13, wherein the nucleophilic organic material comprises:
at least one or more selected from the group consisting of oxalic acid, malic acid, maleic acid, malonic acid, formic acid, lactic acid, acetic acid, picolinic acid, citric acid, succinic acid, tartaric acid, glutaric acid, glutamic acid, glycolic acid, propionic acid, fumaric acid, salicylic acid, pimelinic acid, benzoic acid, butyric acid, aspartic acid, sulfonic acid, and phthalic acid.

15. The polishing slurry composition of claim 13, wherein the nucleophilic organic material is in an amount of 0.001 wt % to 5.0 wt % in the polishing slurry composition.

16. The polishing slurry composition of claim 1, wherein the polishing slurry composition has a zeta potential of 1 millivolt (mV) to 100 mV.

17. The polishing slurry composition of claim 1, wherein a polishing target film is a metal film, an oxide film, or both the metal film and oxide film.

18. The polishing slurry composition of claim 17, wherein the metal comprises:
at least one selected from the group consisting of indium (In), tin (Sn), titanium (Ti), vanadium (V), gadolinium (Gd), gallium (Ga), manganese (Mn), iron (Fe), cobalt (Co), copper (Cu), zinc (Zn), zirconium (Zr), hafnium (HO, aluminum (Al), niobium (Nb), nickel (Ni), chromium (Cr), molybdenum (Mo), tantalum (Ta), ruthenium (Ru), and tungsten.

19. The polishing slurry composition of claim 17, wherein the oxide film comprises:
an oxide comprising at least one selected from the group consisting of indium (In), tin (Sn), silicon (Si), titanium (Ti), vanadium (V), gadolinium (Gd), gallium (Ga), manganese (Mn), iron (Fe), cobalt (Co), copper (Cu), zinc (Zn), zirconium (Zr), hafnium (HO, aluminum (Al), niobium (Nb), nickel (Ni), chromium (Cr), molybdenum (Mo), tantalum (Ta), ruthenium (Ru), and tungsten (W).

20. The polishing slurry composition of claim 17, wherein a polishing speed of the polishing slurry composition for the polishing target film is 100 Å/min or more.

21. The polishing slurry composition of claim 17, wherein polishing selectivity of the polishing target film to a nitride film is 10 or more.

22. The polishing slurry composition of claim 17, wherein selectivity of a polishing speed of the metal film to a static etch rate (SER) of the metal film (the polishing speed of the metal film/the SER of the metal film) is 5 or more.
